(19) United States
(12) Patent Application Publication
(10) Pub. No.: US 2021/0335919 A1
(43) Pub. Date: Oct. 28, 2021

(54) DISPLAY PANEL AND TERMINAL DEVICE THEREOF

(71) Applicant: Wuhan China Star Optoelectronics Semiconductor Display Technology Co., Ltd., Wuhan (CN)

(72) Inventor: Sihang BAI, Wuhan (CN)

(21) Appl. No.: 16/476,282

(22) PCT Filed: Apr. 8, 2019
(86) PCT No.: PCT/CN2019/081745

§ 371 Date: Jul. 6, 2019

(30) Foreign Application Priority Data
Dec. 29, 2018 (CN) 201811635335.5

(51) Int. Cl. H01L 27/32; H01L 51/52

(52) U.S. Cl. CPC H01L 27/3234; H01L 51/5262; H01L 27/326

(57) ABSTRACT

A display panel is provided. It defines a first display area and a second display area, including a substrate layer; the substrate layer includes a first portion, whose location is corresponding to the first display area, and a second portion, whose location is corresponding to the second display area. The second portion of the substrate layer can achieve a transmittance of 80% or more for an entire visible light band. A display panel provided is capable of performing an entire full-screen display, with high light transmittance without a significant non-display area.

### FIELD OF INVENTION

The invention relates to the field of light-emitting display technology, in particular to a display panel and a terminal device thereof.

### BACKGROUND OF INVENTION

It is known that with continuous advancement of technology, touch-screen mobile phones have become indispensable tools for people's daily lives. However, considering convenience of operation, the screen of the mobile phone cannot be increased indefinitely. On the contrary, it is sometimes limited to a certain size. Therefore, this requires a possible increase in a display range within a limited size range. That is, Industry often calls “narrow border” design in order to achieve a larger screen ratio of mobile phones.

Among them, common practice in the industry is to reduce the border area of the display screen. The most effective way to reduce the lower border is pad bending technology, a fan-shaped area (Fanout), a wiring area, a driver IC, and a FPC in a part of the screen being bent together to the back of the screen for bonding, so that length of the lower-border area can be effectively reduced.

However, since a front camera of the mobile phone is generally placed in the upper-border area of the display screen, in order to ensure shooting requirements of the camera, the range of the upper border cannot be continuously reduced, and only the range of lighting area of the camera can be limited. In this regard, the industry uses a “bang” or “drop” screen to achieve the reduction of the border, thereby increasing the screen ratio.

However, regardless of the design, the camera disposed under the display screen is in a non-display area of the display screen, so that there is always a non-display area within the effective display range of the display screen. In order to realize a true full-screen and improve customer's visual experience, it is necessary to combine the camera disposed under the screen in a display area of the display screen, that is, the camera can take a picture normally when the camera takes a photograph, and light transmittance is high. A well, when the camera dose not photograph, the normal image display can still be performed on the display area on the screen.

Referring to FIG. 1, which illustrates a structure of a display area of an OLED display panel commonly used in the industry. As shown in the figure, the display area (AA area) of the display panel is composed of a PI (polyimide) layer 101′, a device array layer 102′, an organic light-emitting (EL) layer 103′, an encapsulation (TFE) layer 104′, a touch (DOT) layer 105′, and a module (MOD) device layer 106′. Film layers having a greatest influence on the transmittance of light in all the above structures are the PI layer, a metal film layer in the device array layer, a cathode film layer in the organic light-emitting layer structure, and each segment of a polarizing plate of light (POL) in the MOD device.

Therefore, if the light transmittance of the PI layer, the metal film layer in the device array layer, and the cathode film layer in the organic light-emitting layer can be increased and the use of the polarizing plate of light can be eliminated simultaneously, the overall light transmittance of the display area can be effectively improved, and at the same time the streamlining process is more conducive to mass production.

### SUMMARY OF INVENTION

One aspect of the present invention is to provide a display panel, which is capable of performing an entire full-screen display, with high light transmittance without a significant non-display area.

The technical solution adopted by the present invention is as follows.

A display panel defines a first display area and a second display area, including a substrate layer; the substrate layer includes a first portion, whose location is corresponding to the first display area, and a second portion, whose location is corresponding to the second display area; the second portion of the substrate layer can achieve a transmittance of 80% or more for an entire visible light band.

Further, in a different embodiment, the transmittance that the second portion of the substrate layer can achieve for the entire visible light band is greater than or equal to the transmittance that the first portion of the substrate layer can achieve for the entire visible light band.

Further, in a different embodiment, the second portion of the substrate layer has a transmittance of 50% or more for a blue-violet band in visible light.

Further, in a different embodiment, the first portion of the substrate layer has a transmittance of 30% or more for a blue-violet band in visible light.

Further, in a different embodiment, the first portion of the substrate layer is formed by using a first PI material and the second portion is formed by using a second PI material; the first material and the second material are disposed in an overlapping manner at a position where the first portion and the second portion meet.

Specifically, the first PI material may be a light yellow PI material commonly used in the industry, and the second PI material is an innovative technical solution disclosed by the present invention, which is preferably a transparent PI material with respect to the commonly used light yellow PI material.

Further, in a different embodiment, the first PI material is different from the second PI material.

Further, in a different embodiment, the substrate layer is provided with a device array layer and the device array layer is provided with a pixel array, wherein the pixel array includes a first pixel array disposed in the first display area and a second pixel array disposed in the second display area, and wherein a density of the pixel array of the first pixel array is greater than a density of the pixel array of the second pixel array at the same unit area. The unit area may be in units of centimeters, millimeters, or micrometers, for example, the unit area may be 1 square millimeter, 1 square centimeter, etc.; which is determined as needed and is not limited.

Further, in a different embodiment, the density of the pixel array of the first pixel array is 1 to 100 times the density of the pixel array of the second pixel array.

For example, in one embodiment, the first pixel array is a 10×10 pixel array and the second pixel array is a 4×4 pixel array under the same unit area.

Further, in still another embodiment, let each pixel size be 63 um*63 um, the number of pixels disposed in the unit square millimeter of the first pixel array is 252, and the density of the pixel array disposed by the second pixel array in the same unit square millimeter may be ¼, 1/9, 1/16, 1/25, 1/36 and so on of the array density of the first pixel array, depending on actual needs and not limited.

Further, in a different embodiment, an area between adjacent pixels in the second pixel array is provided with a light-transmitting channel, wherein the purpose of reducing the density of the second pixel array is to increase the space between the pixels so that more light energy is incident between the pixels to an image sensing unit below the pixel. Therefore, the area between adjacent pixels in the second pixel array should be as transparent as possible, and in order to achieve this purpose, the area between two adjacent pixels can dispose the transparent channel. Further, for the materials used in the structure of each film layer in the light-transmitting channel, it is also preferably made of a material having a high light transmittance. For example, it is not suitable to dispose a pixel definition layer composed of a material having a high optical density coefficient in the area.

Further, in a different embodiment, the device array layer includes a pixel definition layer; the pixel definition layer in the second display area is formed by using a first organic photoresist material, wherein the first organic photoresist material has an optical density (OD) value greater than 0.2. Specifically, it may be 0.2, 0.3, 0.4, 0.5, 0.6, 0.7, 0.8, 0.9, 1.0, 1.1, 1.2, 1.3, 1.5, 1.8, 2, 2.2, 2.5, 2.8, 3, or the like. The pixel definition layer formed by the first organic photoresist material can block the diffraction and reflection phenomenon of incident light, the diffraction and reflection caused by the metal wiring layer in the unit array layer.

Further, in a different embodiment, the first organic photoresist material can be a black photoresist material.

Specifically, in still another embodiment, the first organic photoresist material may be a black photoresist material having an optical density (OD) value greater than 0.2, for example, a black-based resin photoresist material, preferably a black-based acrylate resin photoresist material or the like, but not limited thereto. The specifically selected photoresist material can be used as long as it has a light-shielding effect and the required optical density parameter meets the requirements, while the specific color, for example, black, white, or another color, is not limited. Preferably, the pixel definition layer uses a black photoresist material to reduce the reflection of ambient light on the metal layer and to improve the contrast of the display panel, so that no additional polarizing plate of light is needed.

Further, in a different embodiment, the organic photoresist material used in the pixel definition layer of the first display area may be the first organic photoresist material, or may be the second organic photoresist material which is different from the first organic photoresist material. It can be said that the second organic photoresist material can be an organic photoresist material commonly used in the industry for forming the pixel definition layer, and the first organic photoresist material is an innovative technical solution disclosed in the present invention.

Further, in a different embodiment, the pixel definition layers in the device array layer within the first display area and the second display area adopt the first photoresist material.

Further, in a different embodiment, the first display area encloses the second display area. Or in other embodiments, the second display area is located at an edge position of the display panel, and is surrounded by the first display area on three sides instead of being completely wrapped by the first display area. Or the second display area is located at a corner position of the first display area, and the two sides are in contact with each other. Or the second display area is disposed in parallel with the first display area.

Further, in a different embodiment, the display panel is defined with two or more of the second display areas, and the first display area and the second display area are disposed in contact with each other to form an overall display area of the display panel.

Further, in a different embodiment, the display panel is defined with two or more of the first display areas, and the first display area and the second display area are disposed in contact with each other to form an overall display area of the display panel.

Further, still another embodiment of the present invention provides a terminal device comprising a body, wherein the body is provided with a photosensitive device, and wherein the display panel according to the present invention is disposed on the body, and the photosensitive device is correspondingly disposed under the second display area of the display panel.

Further, in a different embodiment, the terminal device may be any smart terminal device that needs to dispose a display panel and needs to dispose a photosensitive device, such as a camera, under the display panel; for example, a mobile phone, a tablet, a computer, and so on.

Compared with the prior art, the beneficial effects of the present invention are as follows. The invention relates to a display panel which is formed in a specific area of a substrate layer, for example, a camera area, by using a transparent PI material according to the present invention, so that the light transmittance of the area is greatly improved, and so that the camera disposed underneath can get enough light for normal shooting operations. At the same time, the density of the pixel array in the device array layer in the area is reduced, so that the area still has display function. In this way, the display panel according to the present invention has an effective display area as a whole, and there is no non-display area that is compromised to maintain the normal shooting function of the camera below. Thus, to a certain extent, a ‘full-screen’ display effect with high demand on the market is realized. The display effect of the ‘full screen’ obviously improves the satisfaction of the customer who uses the terminal device. Therefore, the display panel according to the present invention can be considered as a development trend of the panel industry.

Further, the pixel definition layer in the unit array layer of the camera area replaces the conventional organic photoresist with the novel functional material, black organic photoresist, according to the present invention. The black photoresist material has absorption properties for light, so that it can play a certain occlusion. Thereby, the phenomenon of the diffraction and reflection of the incident light, caused by the metal wiring in the device array layer, is effectively improved at the position of the camera. The light-leakage phenomenon between different pixels in the light-emitting area can be improved at the same time.

More importantly, due to the light-shielding effect of the black photoresist material introduced, if the pixel definition layer of the overall display area of the display panel adopts the photoresist material according to the present invention, the process of the display panel according to the present invention eliminates the need for a subsequent process of the polarizing plate of light. Thus, the manufacturing process of the display panel according to the present invention is simplified.

In addition, the display panel of the present invention does not need to use a laser cutting method to realize the normal shooting operation of the camera under the screen by the special shaped screen commonly used in the prior art, thereby avoiding the increase in the number of particles and the risk of a crack during the laser process for the screen. At the same time, the invention does not increase the cost of equipment, and is more conducive to future mass production.

### DESCRIPTION OF DRAWINGS

In order to more clearly illustrate the technical solutions in the embodiments of the present invention, the drawings used in the description of the embodiments will be briefly described below. It is obvious that the drawings in the following description are only some embodiments of the present invention. Other drawings can also be obtained from those skilled in the art based on these drawings without paying any creative effort.

FIG. 1 is a schematic structural view of a display area of an OLED display panel commonly used in the industry;

FIG. 2 is a schematic view of a display panel according to an embodiment of the present invention;

FIG. 3 is a partial structural view of the display panel shown in FIG. 2; and

FIG. 4 is a partial cross-sectional structural view of the display panel shown in FIG. 2, which only shows a part of the structure in the device array layer.

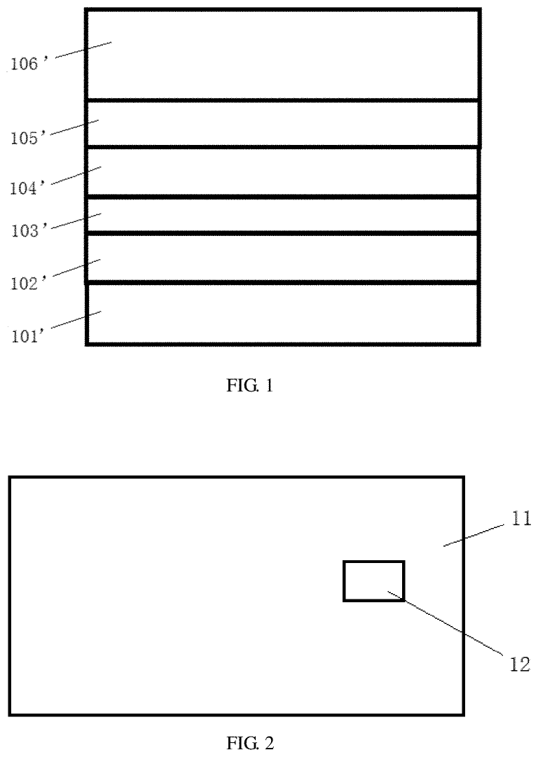

### DETAILED DESCRIPTION OF PREFERRED EMBODIMENTS

Technical solutions of a display panel and its terminal device according to the present invention will be further described in detail below with reference to the accompanying drawings and embodiments.

Referring to FIG. 2, an embodiment of the present invention provides a display panel defining a first display area 11 and a second display area 12. The first display area 11 may be, for example, an AA display area in a so-called display panel, and the second display area 12 may be a display panel area corresponding to a camera on the screen.

As shown in the figure, the first display area is completely wrapped around 4 surfaces of the second display area. In other embodiments, the first display area may be wrapped around 3 surfaces of the second display area, or both display areas may be arranged in parallel connection, which may be determined according to actual needs, and is not limited. In addition, in other embodiments, the number of the first display areas 11 and the second display areas 12 provided on the display panel may be determined as needed, and is not limited.

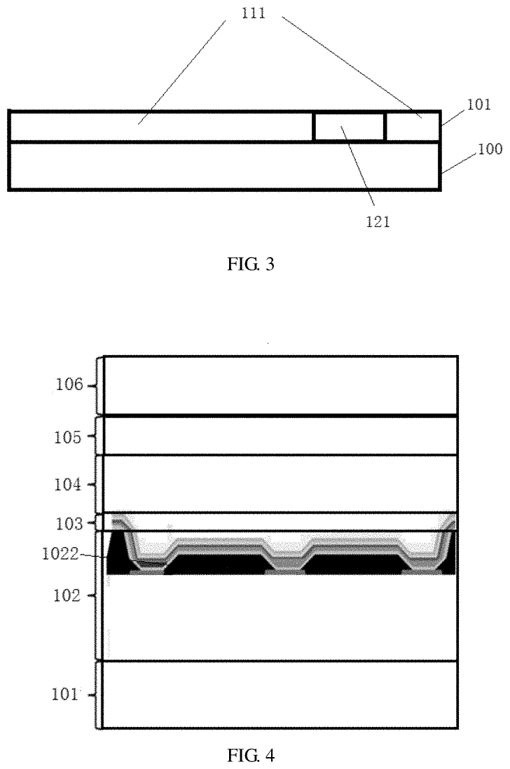

Further, the display panel comprises a glass layer 100, a substrate layer 101, and other functional layers, as shown in FIG. 3, which only illustrates the glass layer 100 and the substrate layer 101 therein. The substrate layer 101 includes a first portion 111 whose location is corresponding to the first display area 11 and a second portion 121 whose location is corresponding to the second display area 12.

The first portion 111 is made of a first PI material, which may be a light yellow PI material commonly used in the industry, wherein the transmittance of a blue-violet light band of visible light is approximately 30%. The second portion 121 is made of a second PI material, which is a transparent PI material having an entire transmittance of visible light of 80% or more, wherein the transmittance of the blue-violet light band of visible light is 50% or more.

The second portion 121 of the substrate layer 101 is made of the transparent PI material, which can effectively improve the transmittance of incident light to a certain extent, so that a corresponding photosensitive device, for example, a camera, or other image sensors can get enough light to ensure that the shooting function can be performed normally.

In other embodiments, the first portion 111 of the substrate layer 101 may also be formed by using the second PI material, but is not limited thereto.

Further, referring to FIG. 4, other functional layers disposed under the substrate layer 101 include a device array layer 102, an organic light-emitting (EL) layer 103, an encapsulation (TFE) layer 104, a touch (DOT) layer 105, and a module (MOD) device layer 106.

The device array layer 102 is provided with a pixel array, wherein the pixel array includes a first pixel array correspondingly disposed in the first display area 11 and a second pixel array correspondingly disposed in the second display area, and wherein a density of the pixel array of the first pixel array is greater than a density of the pixel array of the second pixel array at the same unit area. The unit area may be in units of centimeters or millimeters, which is determined as needed and is not limited.

The density of the pixel array of the first pixel array is 1 to 10 times the density of the pixel array of the second pixel array. For example, in one embodiment, the first pixel array is a 10×10 pixel array and the second pixel array is a 4×4 pixel array under the same unit area.

Specifically, let each pixel size be 63 um*63 um, the number of pixels disposed in the unit square millimeter of the first pixel array is 252, and the density of the pixel array disposed by the second pixel array in the same unit square millimeter may be ¼, 1/9, 1/16, 1/25, 1/36 and so on of the array density of the first pixel array, depending on actual needs and not limited.

The present invention reduces the density of the pixel array corresponding to the second display area 12 by using a sparse array arrangement. In this way, while the display function of the second display area 12 is retained, the function of not affecting the light transmission can be performed. Then, this way does not affect the normal function implementation of the photosensitive device disposed under it due to the retention of the display function.

Further, an area between adjacent pixels in the second display area 12 is provided with a light-transmitting channel, wherein the purpose of reducing the density of the pixel array in the second display area 12 is to increase the space between the pixels so that more light energy is incident from the area between the pixels to an image sensing unit below it. Therefore, the area between adjacent pixels in the second display area 12 should be as transparent as possible, and the area between the two pixels can be defined as the transparent channel. Further, for the materials used in the structure of each film layer in the light-transmitting channel, it is also preferably made of a material having a high light transmittance. For example, it is not suitable to dispose a pixel definition layer composed of a material having a high optical density coefficient in the area.

Further, the unit array layer 102 includes a pixel definition layer 1022, wherein the photoresist material used by the pixel definition layer 1022 can block diffraction and reflection of incident light, the diffraction and reflection caused by the metal wiring layer in the unit array layer 102. For example, the pixel definition layer 1022 is a black photoresist material having an optical density OD (Optical Density; OD=−IgT, where T is the transmittance) value greater than 0.2, preferably 0.3 or above.

The change of the photoresist material is, in terms of technical effect, taking the second display area as an example, which can effectively improve the phenomenon of diffraction and reflection of the metal film layer in the device array layer 102 at the position thereof. The light-leakage phenomenon between different pixels in the light-emitting area can also be improved simultaneously. More importantly, if the pixel definition layer of the overall display area of the display panel adopts the photoresist material according to the present invention, the subsequent POL process can be removed, which simplifies the process of the display panel to some extent.

Further, still another embodiment of the present invention provides a terminal device comprising a body, wherein the body is provided with a photosensitive device, such as a camera. The display panel according to the present invention is further disposed on the body, wherein the photosensitive device is correspondingly disposed under the second display area of the display panel.

The terminal device may be any smart terminal device that needs to dispose a display panel and dispose a photosensitive device under the display panel; for example, a mobile phone, a tablet, a computer, and so on.

The invention relates to a display panel which is formed in a specific area of a substrate layer, for example, a camera area, by using a transparent PI material according to the present invention, so that the light transmittance of the area is greatly improved, and so that the camera disposed underneath can get enough light for normal shooting operations. At the same time, the density of the pixel array in the device array layer in the area is reduced, so that the area still has display function. In this way, the display panel according to the present invention has an effective display area as a whole, and there is no non-display area that is compromised to maintain the normal shooting function of the camera below. Thus, to a certain extent, a ‘full-screen’ display effect with high demand on the market is realized. The display effect of the ‘full screen’ obviously improves the satisfaction of the customer who uses the terminal device. Therefore, the display panel according to the present invention can be considered as a development trend of the panel industry.

Further, the pixel definition layer in the unit array layer of the camera area replaces the conventional organic photoresist with the novel functional material, black organic photoresist, according to the present invention. The black photoresist material has absorption properties for light, so that it can play a certain occlusion. Thereby, the phenomenon of the diffraction and reflection of the incident light, caused by the metal wiring in the device array layer, is effectively improved at the position of the camera. The light-leakage phenomenon between different pixels in the light-emitting area can be improved at the same time.

More importantly, due to the light-shielding effect of the black photoresist material introduced, if the pixel definition layer of the overall display area of the display panel adopts the photoresist material according to the present invention, the process of the display panel according to the present invention eliminates the need for a subsequent POL process. Thus, the manufacturing process of the display panel according to the present invention is simplified.

In addition, the display panel of the present invention does not need to use a laser cutting method to realize the normal shooting operation of the camera under the screen by the special shaped screen commonly used in the prior art, thereby avoiding the increase in the number of particles and the risk of a crack during the laser process for the screen. At the same time, the invention does not increase the cost of equipment, and is more conducive to future mass production.

The technical scope of the present invention is not limited to the above description, and those skilled in the art can make various modifications and changes to the above embodiments without departing from the technical idea of the present invention. These modifications and changes are within the scope of the invention.

What is claimed is:

1. A display panel, defining a first display area and a second display area, and comprising a substrate layer;
wherein the substrate layer includes a first portion, whose location is corresponding to the first display area, and a second portion, whose location is corresponding to the second display area; and
wherein the second portion of the substrate layer achieves a transmittance of 80% or more for an entire visible light band.

2. The display panel as claimed in claim 1, wherein the transmittance that the second portion of the substrate layer achieves for the entire visible light band is greater than or equal to the transmittance that the first portion of the substrate layer achieves for the entire visible light band.

3. The display panel as claimed in claim 1, wherein the first portion of the substrate layer is formed by using a first PI (polyimide) material and the second portion is formed by using a second PI material, and wherein the first material and the second material are disposed in an overlapping manner at a position where the first portion and the second portion meet.

4. The display panel as claimed in claim 1, wherein the second portion has a transmittance of 50% or more for a blue-violet band in visible light.

5. The display panel as claimed in claim 1, wherein the substrate layer is provided with a device array layer and the device array layer is provided with a pixel array, wherein the pixel array includes a first pixel array disposed in the first display area and a second pixel array disposed in the second display area, and wherein a density of the pixel array of the first pixel array is greater than a density of the pixel array of the second pixel array at the same unit area.

6. The display panel as claimed in claim 5, wherein an area between adjacent pixels in the second pixel array is provided with a light-transmitting channel.

7. The display panel as claimed in claim 5, wherein the density of the pixel array of the first pixel array is 1 to 100 times the density of the pixel array of the second pixel array.

8. The display panel as claimed in claim 1, wherein the substrate layer is provided with a device array layer, and the device array layer includes a pixel definition layer, wherein the pixel definition layer in the second display area is formed by using a first organic photoresist material, and wherein the first organic photoresist material has an optical density (OD) value greater than 0.2.

9. The display panel as claimed in claim 1, wherein the substrate layer is provided with a device array layer, and the device array layer includes a pixel definition layer, and wherein the pixel definition layer in the second display area is formed by using a black organic photoresist material.

10. A terminal device, comprising a body, wherein the body is provided with a photosensitive device, and wherein the display panel as claimed in claim 1 is disposed on the body, and the photosensitive device is correspondingly disposed under the second display area of the display panel.
